(19) United States
(12) Patent Application Publication
(10) Pub. No.: US 2006/0223216 A1
(43) Pub. Date: Oct. 5, 2006

(54) Sensor module structure and method for fabricating the same

(76) Inventors: Chin-Huang Chang, Taichung (TW); Chien-Ping Huang, Taichung (TW); Chih-Ming Huang, Taichung (TW); Cheng-Yi Chang, Taichung (TW); Cheng-Hsu Hsiao, Taichung (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/208,269

(22) Filed: Aug. 18, 2005

(30) Foreign Application Priority Data
Mar. 29, 2005 (TW) 094109707

(51) Int. Cl. H01L 21/00; H01L 23/495

(52) U.S. Cl. 438/64

(57) ABSTRACT

A sensor module structure and a method for fabricating the same are proposed. A chip carrier module plate including a plurality of chip carriers is provided, each chip carrier having a first surface and a second surface. At least one semiconductor chip is mounted on and electrically connected to the first surface of each of the chip carriers. An encapsulation body is formed for completely encapsulating the semiconductor chips and the first surfaces of the chip carriers. A singulation process is performed to form individual package units integrated with the semiconductor chips. A sensor chip, a corresponding lens kit and a flexible printed circuit (FPC) board are attached to the second surface of each of the chip carriers, wherein the sensor chip and the FPC board are electrically connected to the chip carrier. This provides the sensor module structure fabricated with simple processes, low costs and high yields.

### FIELD OF THE INVENTION

The present invention relates to sensor module structures and methods for fabricating the same, and more particularly, to a module structure integrated with a sensor chip, and a method for fabricating the module structure.

### BACKGROUND OF THE INVENTION

FIG. 1 shows a conventional image sensor package disclosed by U.S. Pat. No. 6,696,752, which comprises a sensor chip 10 mounted in a pre-molded cavity of a lead frame 11 and electrically connected to the lead frame 11 via a plurality of bonding wires 12; and a glass member 13 provided above the sensor chip 10 to seal the cavity such that image light can be captured by the sensor chip 10. The fabricated image sensor package can be integrated to an external device such as a printed circuit board (PCB) and is ready for use in an electronic product such as a digital camera, digital video camera, optical mouse, mobile phone, fingerprint recognizer, and so on.

In response to development of miniaturized electronic products and a functional integration requirement of the electronic products, multi-functional portable electronic products such as a combined product of mobile phone and digital camera have been proposed. Accordingly, the semiconductor manufacturers have endeavored to develop Multi Chip Modules (MCMs) capable of incorporating a plurality of chips, so to be suitably applied to the compact electronic products having multiple functionality, high electrical performances and high operation speeds.

FIG. 2 shows an integrated sensor module structure disclosed by U.S. Pat. No. 6,661,089, wherein a sensor-chip control unit 24 such as a digital signal processor (DSP) is integrated in a sensor package mounted with a sensor chip 20 therein, to reduce the size of the sensor module structure for use in an electronic product.

FIGS. 3 and 4 show other types of integrated sensor module structures disclosed by U.S. Pat. Nos. 6,686,588 and 6,384,397 respectively. Referring to FIG. 3, in the module structure disclosed by U.S. Pat. No. 6,686,588, a sensor chip 30 is mounted on an upper surface of a substrate 31, and electronic elements 34 such as control units are attached to a lower surface of the substrate 31 by surface mount technology (SMT) and a packaging process. Referring to FIG. 4, in the module structure disclosed by U.S. Pat. No. 6,384,397, an optical lens 45 is provided on an upper surface of a sensor package 4, and also a flexible circuit board 47 is disposed on the upper surface of the sensor package 4 via a plurality of solder bumps 46, such that electronic signals from the sensor package 4 can be linked to an electronic product through the flexible circuit board 47, making the sensor package able to be integrated with other electronic elements to provide multiple functions for the electronic product.

However, in the foregoing sensor module structures, certain space must be reserved for receiving the packages, which is not favorable for reducing the size of the sensor module structures. Further, to accomplish such sensor module structures, various semiconductor packages should be additionally fabricated and multiple times of SMT implementation are required to incorporate the various semiconductor packages in the sensor module structures. This not only makes the fabrication processes more complicated but also increases the fabrication costs. Moreover, it needs to integrate different functional electronic elements into the sensor packages for the sensor module structures, such that a batch-type fabrication method is not suitably used and the industrial applications are limited.

Therefore, the problem to be solved here is to provide a sensor module structure and a fabrication method thereof, such that the sensor module structure is fabricated with low costs and simple processes, has a reduced size and high integration, and can be subjected to mass production in a batch-type manner.

### SUMMARY OF THE INVENTION

In light of the foregoing drawbacks in the conventional technology, an objective of the present invention is to provide a sensor module structure with low costs and high integration, and a method for fabricating the same.

Another objective of the present invention is to provide a sensor module structure and a method for fabricating the same, using simple processes to fabricate the sensor module structure.

Still another objective of the present invention is to provide a sensor module structure having a reduced size, and a method for fabricating the same.

A further objective of the present invention is to provide a sensor module structure and a method for fabricating the same, using a batch-type manner to perform mass production of the sensor module structure.

In order to achieve the above and other objectives, the present invention proposes a method for fabricating sensor module structure, comprising the steps of: preparing a chip carrier module plate comprising a plurality of array-arranged chip carriers, wherein each of the chip carriers has a first surface and a second surface opposed to the first surface; mounting at least one semiconductor chip on the first surface of each of the chip carriers, and electrically connecting the semiconductor chips to the chip carriers; forming an encapsulation body for completely encapsulating the semiconductor chips and the first surfaces of the chip carriers; performing a singulation process to form individual package units integrated with the semiconductor chips; and attaching a sensor chip, a corresponding lens kit and a flexible printed circuit (FPC) board to the second surface of each of the chip carriers, wherein the sensor chip and the FPC board are electrically connected to the corresponding chip carrier. The chip carrier is a substrate such as LGA (land grid array) substrate. The semiconductor chips can be electrically connected to the first surfaces of the chip carriers by a wire-bonding technique or a flip-chip technique, or can be mounted in a stacked manner on the chip carriers. The sensor chip mounted on the second surface of each of the chip carriers can be a wire-bonding type sensor chip or a CSP (chip size package) type sensor chip.

Further, the sensor module structure formed by the above method in the present invention can be fabricated in a batch-type manner, or fabricated one by one under appropriate practical conditions.

The present invention also proposes a sensor module structure, comprising a chip carrier having a first surface and a second surface opposed to the first surface; at least one semiconductor chip mounted on and electrically connected to the first surface of the chip carrier; an encapsulation body for completely encapsulating the semiconductor chip and the first surface of the chip carrier; at least one sensor chip mounted on and electrically connected to the second surface of the chip carrier; and at least one FPC board mounted on and electrically connected to the second surface of the chip carrier.

Optionally, a passive component is mounted on the first/second surface of the chip carrier to improve the electrical performance of the sensor module structure. The sensor module structure may further comprises a heat dissipating structure disposed on the encapsulation body to improve the heat dissipating performance of the sensor module structure.

Therefore, in the sensor module structure and the method for fabricating the same according to the present invention, firstly functional semiconductor chips other than sensor chips are packaged in a quick batch-type manner, and then sensor chips and FPC boards are mounted to exposed portions of chip carriers of the package units, to thereby form highly integrated sensor module structures, such that the sensor module structures with a reduced size can be achieved by using cost-effective and simple fabrication processes. Moreover, the sensor module structures combining the sensor chips and other functional semiconductor chips can be produced in the batch-type manner in the present invention, thereby avoiding the drawbacks of complicating the fabrication processes and increasing the fabrication costs in the conventional technology due to additional fabrication of various semiconductor packages for the conventional sensor module structures and multiple times of SMT implementation for incorporating the various semiconductor packages in the conventional sensor module structures.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of an image sensor package disclosed in U.S. Pat. No. 6,696,752;

FIG. 2 (PRIOR ART) is a cross-sectional view of an integrated sensor module structure disclosed in U.S. Pat. No. 6,661,089;

FIG. 3 (PRIOR ART) is a cross-sectional view of an integrated sensor module structure disclosed in U.S. Pat. No. 6,686,588;

FIG. 4 (PRIOR ART) is a cross-sectional view of an integrated sensor module structure disclosed in U.S. Pat. No. 6,384,397;

FIGS. 5A to 5E are cross-sectional diagrams showing steps of a method for fabricating sensor module structure according to a first preferred embodiment of the present invention;

FIG. 6 is a cross-sectional view of a sensor module structure according to a second preferred embodiment of the present invention;

FIG. 7 is a cross-sectional view of a sensor module structure according to a third preferred embodiment of the present invention;

FIGS. 8A and 8B are cross-sectional views of a sensor module structure according to a fourth preferred embodiment of the present invention; and

FIGS. 9A and 9B are cross-sectional views of a sensor module structure according to a fifth preferred embodiment of the present invention.

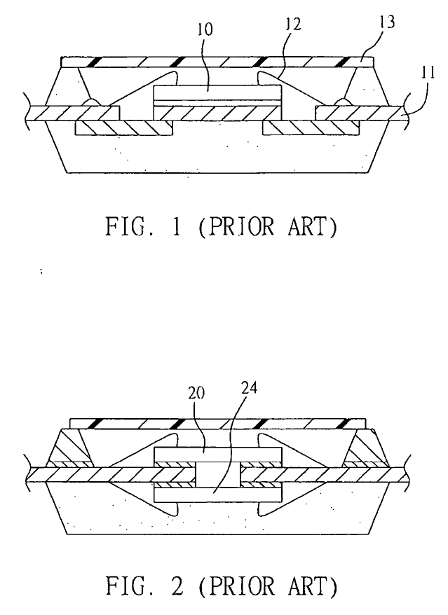

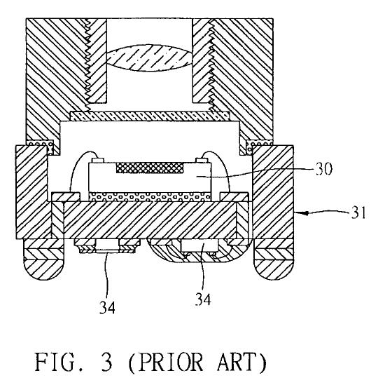

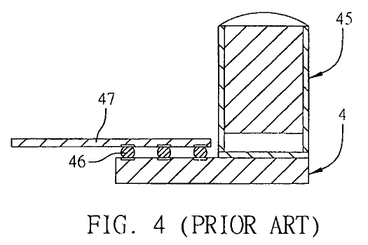

### DETAILED DESCRIPTION OF THE PREFERRED EMBODIMENTS

First Preferred Embodiment

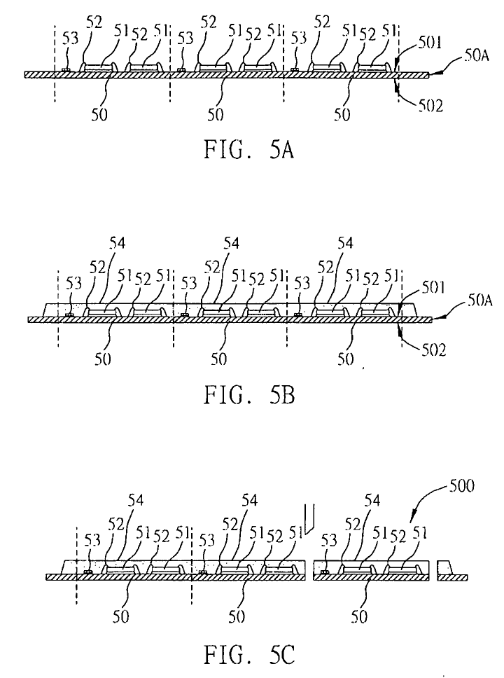

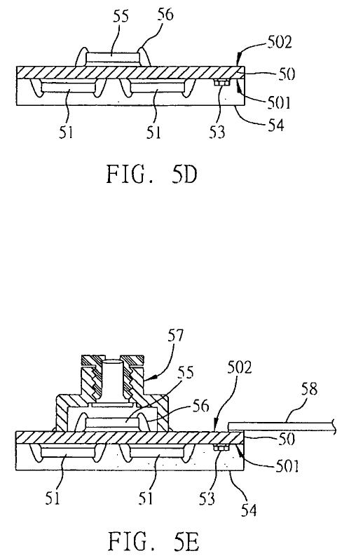

FIGS. 5A-5E are cross-sectional diagrams showing steps of a method for fabricating sensor module structure according to a first preferred embodiment of the present invention.

Referring to FIG. 5A, a chip carrier module plate such as a substrate module plate 50A is provided, which comprises a plurality of array-arranged chip carriers such as substrates 50. Each of the substrates 50 has a first surface 501 and a second surface 502 opposed to the first surface 501. At least one semiconductor chip 51 is mounted on the first surface 501 of each of the substrates 50, and is electrically connected to the first surface 501 of the corresponding substrate 50 via a plurality of bonding wires 52. Optionally, a passive component 53 is disposed on the first surface 501 of the substrate 50 according to a practical electrical requirement. The substrate 50 can be a LGA (land grid array) substrate. The semiconductor chip 51 can be a functional semiconductor chip such as MCU (micro control unit), memory unit and so on. Besides in an array, the substrates 50 of the substrate module plate 50A may also be arranged in a strip; or single substrates can be used under appropriate fabrication conditions.

Referring to FIG. 5B, the substrate module plate 50A mounted with the semiconductor chips 51 and the passive components 53 is placed into a molding cavity of an encapsulation mold (not shown) to perform a molding process by which an encapsulation body 54 is formed for completely encapsulating the semiconductor chips 51, the bonding wires 52, the passive components 53 and the first surfaces 501 of the substrates 50.

Referring to FIG. 5C, a singulaiton process is performed to cut the encapsulation body 54 and the substrate module plate 50A to thereby form a plurality of package units 500 integrated with the semiconductor chips 51.

Referring to FIG. 5D, for each of the package units 500, a sensor chip 55 is mounted on the second surface 502 of the substrate 50, and is electrically connected to the substrate 50 via a plurality of bonding wires 56, wherein the sensor chip 55 has a sensing area 550 for allowing the sensor chip 55 to receive light.

Referring to FIG. 5E, for each of the package units 500, a lens kit 57 is provided, which includes a lens 57a, a lens holder 57b, a focusing mechanism 57c, and an infrared (IR) filter 57d. The lens kit 57 is mounted on the second surface 502 of the substrate 50 at a position corresponding to the sensor chip 55, for allowing image to be captured by the sensing area 550 of the sensor chip 55 through the lens kit 57, such that a sensor module structure integrating the functional semiconductor chip 51 and the sensor chip 55 is formed. A FPC board 58 is mounted on and electrically connected to electrical contacts on the second surface 502 of the substrate 50 by a conductive material, such that the sensor module structure can be electrically connected to an external device through the FPC board 58.

By the foregoing fabrication method, a sensor module structure is provided in the present invention as shown in FIG. 5E, comprising: a chip carrier such as a substrate 50 having a first surface 501 and a second surface 502 opposed to the first surface 501; at least one semiconductor chip 51 mounted on and electrically connected to the first surface 501 of the substrate 50; an encapsulation body 54 for completely encapsulating the semiconductor chip 51 and the first surface 501 of the substrate 50; at least one sensor chip 55 and a corresponding lens kit 57 mounted on the second surface 502 of the substrate 50, wherein the sensor chip 55 is electrically connected to the substrate 50; and at least one FPC board 58 mounted on and electrically connected to the second surface 502 of the substrate 50.

Therefore, in the sensor module structure and the method for fabricating the same according to the present invention, firstly functional semiconductor chips other than sensor chips are packaged in a quick batch-type manner, and then sensor chips and FPC boards are mounted to the bottom portions of chip carriers of the package units, to thereby form highly integrated sensor module structures, such that the sensor module structures with a reduced size can be achieved by using cost-effective and simple fabrication processes. Moreover, the sensor module structures combining the sensor chips and other functional semiconductor chips can be produced in the batch-type manner in the present invention, thereby avoiding the drawbacks of complicating the fabrication processes and increasing the fabrication costs in the conventional technology due to additional fabrication of various semiconductor packages for the conventional sensor module structures and multiple times of SMT implementation for incorporating the various semiconductor packages in the conventional sensor module structures.

Second Preferred Embodiment

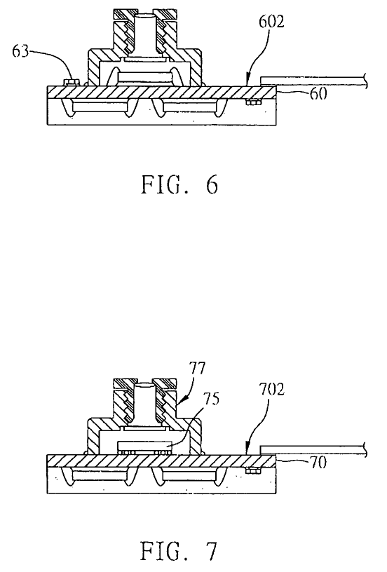

FIG. 6 is a cross-sectional view of a sensor module structure according to a second preferred embodiment of the present invention.

The sensor module structure in the second embodiment is fabricated by a method similar to that for the first embodiment, with a difference in that in the second embodiment, as shown in FIG. 6, a passive component 63 can further be mounted on a second surface 602 of a substrate 60 to improve the electrical performance of the sensor module structure.

Third Preferred Embodiment

FIG. 7 is a cross-sectional view of a sensor module structure according to a third preferred embodiment of the present invention.

The sensor module structure in the third embodiment is fabricated by a method similar to that for the first embodiment, with a difference in that in the third embodiment, as shown in FIG. 7, a sensor chip 75 mounted on a second surface 702 of a substrate 70 can be electrically connected to the substrate 70 by a chip size packaging (CSP) technique, and then a lens kit 77 is disposed on the second surface 702 of the chip carrier 70 at a position corresponding to the sensor chip 75, for allowing image to be captured by the sensor chip 75.

Fourth Preferred Embodiment

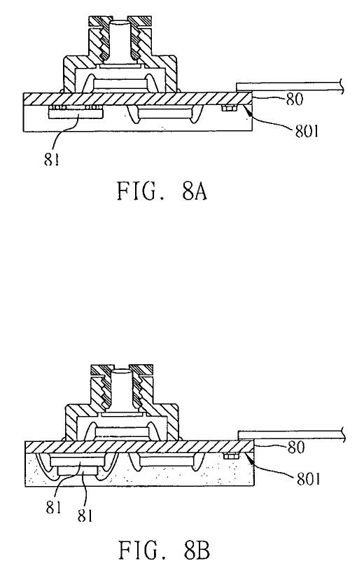

FIGS. 8A and 8B are cross-sectional views of a sensor module structure according to a fourth preferred embodiment of the present invention.

The sensor module structure in the fourth embodiment is fabricated by a method similar to that for the first embodiment, with a difference in that in the fourth embodiment, as shown in FIG. 8A, a semiconductor chip 81 mounted on a first surface 801 of a substrate 80 can be electrically connected to the first surface 801 of the substrate 80 by a flip-chip technique. Alternatively, as shown in FIG. 8B, a plurality of semiconductor chips 81 can be stacked on the first surface 801 of the substrate 80 to improve the electrical performance of the sensor module structure.

Fifth Preferred Embodiment

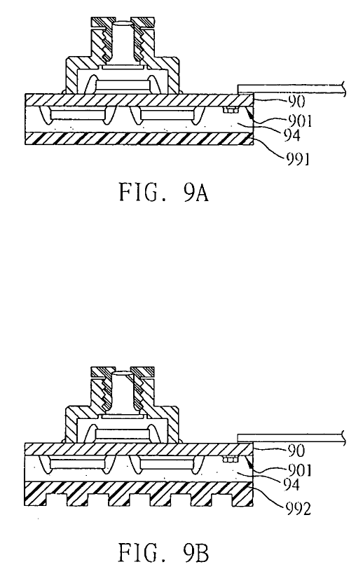

FIGS. 9A and 9B are cross-sectional views of a sensor module structure according to a fifth preferred embodiment of the present invention.

The sensor module structure in the fifth embodiment is fabricated by a method similar to that for the first embodiment, with a difference in that in the fifth embodiment, a heat sink 991 (as shown in FIG. 9A) or a surface-corrugated heat dissipating structure 992 (as shown in FIG. 9B) can be mounted on a surface of an encapsulation body 94 corresponding to a first surface 901 of a substrate 90 so as to improve the heat dissipating performance of the sensor module structure.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A method for fabricating sensor module structure, comprising:
preparing a chip carrier module plate comprising a plurality of chip carriers, each of the chip carriers having a first surface and a second surface, wherein at least one semiconductor chip is mounted on and electrically connected to the first surface of each of the chip carriers;
forming an encapsulation body for completely encapsulating the semiconductor chips and the first surfaces of the chip carriers;
performing a singulation process to form individual package units integrated with the semiconductor chips; and
attaching a sensor chip, a corresponding lens kit and a flexible printed circuit (FPC) board to the second surface of each of the chip carriers, and electrically connecting the sensor chip and the FPC board to each of the chip carriers.

2. The method of claim 1, wherein the chip carriers are substrates arranged in an array or a strip.

3. The method of claim 2, wherein the chip carriers are land grid array (LGA) substrates.

4. The method of claim 1, wherein the semiconductor chip is electrically connected to the chip carrier by a wire-bonding technique or a flip-chip technique.

5. The method of claim 1, further comprising a passive component mounted on the first/second surface of the chip carrier.

6. The method of claim 1, wherein the semiconductor chip is a functional semiconductor chip selected from one of micro control unit (MCU) and memory unit.

7. The method of claim 1, wherein the sensor chip is a wire-bonding type sensor chip or a chip size package (CSP) type sensor chip.

8. The method of claim 1, wherein the FPC board is mounted to electrical contacts on the second surface of the chip carrier by a conductive material.

9. The method of claim 1, wherein the at least one semiconductor chip comprises a plurality of semiconductor chips stacked on the first surface of the chip carrier.

10. The method of claim 1, wherein a surface of the encapsulation body corresponding to the first surface of the chip carrier is provided with a heat sink or a surface-corrugated heat dissipating structure thereon.

11. A sensor module structure comprising:
a chip carrier having a first surface and a second surface; at least one semiconductor chip mounted on and electrically connected to the first surface of the chip carrier;
an encapsulation body for completely encapsulating the semiconductor chip and the first surface of the chip carrier;
at least one sensor chip and a corresponding lens kit mounted on the second surface of the chip carrier, wherein the sensor chip is electrically connected to the chip carrier; and
at least one flexible printed circuit (FPC) board mounted on and electrically connected to the second surface of the chip carrier.

12. The sensor module structure of claim 11, wherein the chip carrier is a substrate.

13. The sensor module structure of claim 12, wherein the chip carrier is a land grid array (LGA) substrate.

14. The sensor module structure of claim 11, wherein the lens kit includes a lens, a lens holder, a focusing mechanism, and an infrared filter.

15. The sensor module structure of claim 11, wherein the semiconductor chip is electrically connected to the chip carrier in a wire-bonding manner or a flip-chip manner.

16. The sensor module structure of claim 11, further comprising a passive component mounted on the first/second surface of the chip carrier.

17. The sensor module structure of claim 11, wherein the semiconductor chip is a functional semiconductor chip selected from one of micro control unit (MCU) and memory unit.

18. The sensor module structure of claim 11, wherein the sensor chip is a wire-bonding type sensor chip or a chip size package (CSP) sensor chip.

19. The sensor module structure of claim 11, wherein the FPC board is mounted to electrical contacts on the second surface of the chip carrier by a conductive material.

20. The sensor module structure of claim 11, wherein the at least one semiconductor chip comprises a plurality of semiconductor chips stacked on the first surface of the chip carrier.

21. The sensor module structure of claim 11, wherein a surface of the encapsulation body corresponding to the first surface of the chip carrier is provided with a heat sink or a surface-corrugated heat dissipating structure thereon.
